(19) United States
(12) Patent Application Publication
(10) Pub. No.: US 2012/0256308 A1
(43) Pub. Date: Oct. 11, 2012

(54) Method for Sealing a Micro-Cavity

(75) Inventor: Philippe Helin, Wezembeek-Oppem (BE)

(73) Assignee: IMEC, Leuven (BE)

(21) Appl. No.: 13/444,665

(22) Filed: Apr. 11, 2012

Related U.S. Application Data
(60) Provisional application No. 61/474,014, filed on Apr. 11, 2011.

(51) Int. Cl. H01L 23/04; H01L 21/56

(52) U.S. Cl. 257/704; 438/51; 257/E23.181; 257/E21.502

(57) ABSTRACT

A method for sealing a cavity is disclosed. The method includes depositing a membrane layer on top of a sacrificial layer, etching release holes into the membrane layer, and removing at least a portion of the sacrificial layer through the release holes to form a cavity. Prior to removing the sacrificial layer portion, the method includes producing a narrowing layer on the side walls of the release holes. The narrowing layer can be a sealing layer that seals off the release holes after a reflow step. Alternatively, the narrowing layer can be a layer that does not have a sealing function and is used to narrow the holes, allowing the holes to be sealed without a sealing or other material entering the cavity. The narrowing layer may be deposited by conformal deposition followed by an anisotropic etch or by direct deposition on the side walls of the release holes.

### CROSS REFERENCE TO RELATED APPLICATIONS

Pursuant to the provisions of 35 U.S.C. §119(e), this application claims priority to U.S. Provisional Application Ser. No. 61/474,014 filed Apr. 11, 2011, the entire contents of which are incorporated herein by reference.

### FIELD

The present invention is related to microelectronic process technology. In particular, it relates to Micro and Nano Electromechanical Systems (MEMS and NEMS) process technology. The present invention relates to a method for forming a hermetically sealed micro-cavity and its use in a process flow to provide the capping part of a MEMS or NEMS device.

### BACKGROUND

Many MEMS devices require a hermetic encapsulation under vacuum or under a controlled atmosphere and pressure in order to ensure good performance or an acceptable operational lifetime. The encapsulation has to be performed without the deposition of sealing material on the MEMS device because the sealing material can cause damage to the device. Several approaches are known for device encapsulation with zero-level packaging or wafer-level packaging, where the package is designed and fabricated at the same time as the MEMS device.

In EP1433741, a zero-level packaging method is described based on closing an opening in a membrane using a reflow material, the opening being located above an underlying cavity in a substrate. The method includes depositing an intermediate layer onto the membrane layer that narrows the openings to be sealed. Next, a reflow layer is deposited on the intermediate layer under a first set of pressure and atmosphere conditions to further partially close the openings. Then, the reflow layer is reflowed under a second set of pressure and atmosphere conditions to close the openings. This method allows hermetic sealing of openings in a film at controllable atmosphere and pressure. When using this method, however, some material of the different deposited layers passes through the openings and is deposited on the fragile MEMS devices, which affects proper operation of the devices.

In “Wafer level encapsulation technology for MEMS devices using an HF-permeable PECVD SiOC capping layer” MEMS2008 pp 798-801, a zero-level packaging method is described based on the use of a porous layer to avoid deposition inside the cavity. The method includes the deposition of a porous layer after the patterning of the release holes. This step is followed by a release step in order to get free the MEMS structure. Therefore, the porous layer will prevent the deposition inside the cavity of the next layers to seal this cavity.

In order to use this method, however, the release holes are necessarily limited to the range of few micrometers to provide enough mechanical stiffness of this porous layer to withstand the process operations in the different tools. On the other hand, the definition of the isolation trenches in the capping part to define the electrical connections of the device requires larger openings to avoid parasitic capacitance between the different pads and cap. Due to the size of this opening, the porous layer will not survive the needed process steps (e.g., during cleaning operations the surface of the wafer is exposed to liquid with several bars of pressure) and especially the required metallization of the pads needed for the wirebonding step cannot be done through a simple deposition due to the risk of shortcut. Indeed, the porous layer will be covered by this metallization providing a shortcut between the two parts at differential potential.

### SUMMARY

The present invention is related to a method for sealing a cavity, preferably a cavity where a MEMS or NEMS device is located. According to the method, a membrane layer is deposited on top of a sacrificial layer, after which release holes are etched in the membrane layer and a release step is performed. At least a portion of the sacrificial layer is then removed through the release holes to form the cavity.

Before the release step, a narrowing layer is produced on the side walls of the release holes. The narrowing layer can be a sealing layer that seals off the release holes after a reflow step. Alternatively, the narrowing layer can be a layer that does not have a sealing function. The non-sealing narrowing layer narrows the holes so as to be able to seal off the holes without the danger of sealing or other material entering the cavity. The narrowing layer may be deposited by conformal deposition followed by an anisotropic etch or by direct deposition on the side walls of the release holes.

The term ‘sealing layer’ in the present context means a layer whose function it is within the method to seal off the release holes, either directly or after a reflow step. A ‘non-sealing layer’ is a layer which does not have this function in the method.

In one embodiment, a method for sealing a cavity includes providing a substrate, depositing a sacrificial layer on the substrate, depositing a membrane layer on the sacrificial layer, etching at least one release hole in the membrane layer exposing the sacrificial layer, forming a layer on the side walls of the release hole(s) narrowing the holes, and removing via the release hole(s) at least a portion of the sacrificial layer, so as to form a cavity.

The narrowing layer may or may not be a sealing layer. If the narrowing layer is a sealing layer, the method further includes closing the release holes by reflow of the sealing layer. If the narrowing layer is not a sealing layer, the method further includes depositing a sealing layer on top of the membrane and closing the release holes directly or by reflow of the sealing layer.

According to an embodiment, forming a narrowing layer includes depositing a conformal layer on the membrane layer, and on the side walls and bottom of the release hole(s), and anisotropically etching the conformal layer, leaving the conformal layer only on the side walls of the release hole(s).

According to another embodiment, forming a narrowing layer includes depositing selectively the sealing layer on the side walls of the release hole(s).

According to an embodiment, while etching the release hole(s), the membrane layer is etched to form a cap structure above the location where the cavity is created and/or to form contact pads.

The method may further include depositing a metal layer on the membrane layer.

The sealing layer may be a metal or metal alloy layer. The sealing layer may comprise or consist of aluminium, germanium, gold or indium. The sealing layer may be formed of a stack of layers.

According to another embodiment, the substrate includes one or more MEMS or NEMS devices, and removing the sacrificial layer is performed so as to form a cavity comprising one or more MEMS or NEMS devices.

According to another embodiment, the substrate is formed of a base substrate, an insulator layer on the base substrate, and a structural semiconductor layer comprising one or more MEMS or NEMS devices on the insulating layer, and at least a portion of the insulating layer is removed together with the sacrificial layer, through the release holes, so as to form the cavity comprising one or more MEMS or NEMS devices.

A MEMS device and/or a NEMS device may be encapsulated in a cavity covered by a cap, the cap having a top surface and side walls, wherein release holes are present in the cap, the release holes being sealed by a portion of sealing material, wherein a layer of the sealing material is present on the side walls of the release holes.

According to an embodiment, a layer of the sealing material is present on the side walls of the cap, the layer having a portion on the lower rim of the side walls, the portion having a higher thickness than the rest of the layer, the portion extending downward from the rim.

A device may further comprise a metal layer on the top surface of the cap.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE FIGURES

FIG. 1 illustrates a method according to a first embodiment, where the narrowing layer is a sealing layer.

FIG. 2 illustrates a method according to a second embodiment, where the narrowing layer is not a sealing layer.

FIG. 3 illustrates a process flow for producing a MEMS device according the first embodiment.

### DETAILED DESCRIPTION

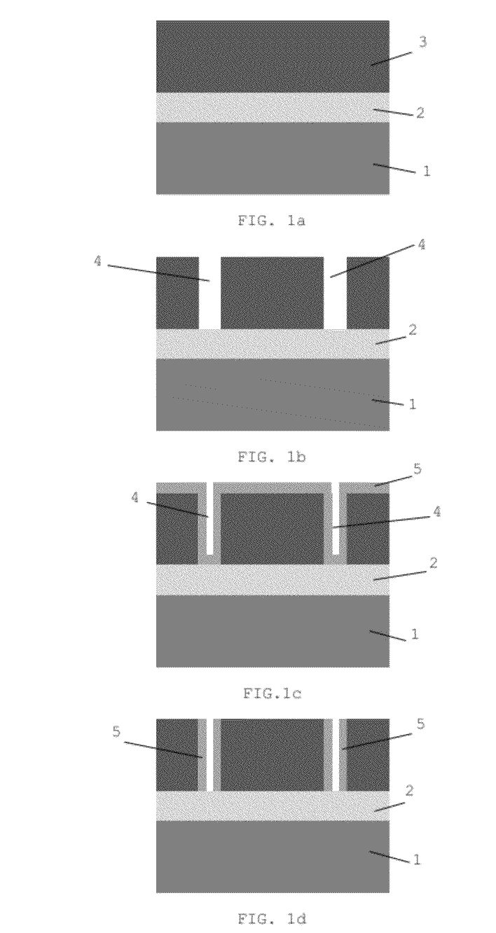

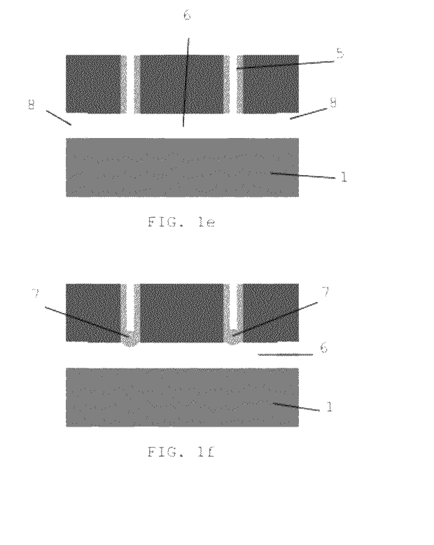

FIG. 1 illustrates a method for sealing a cavity, according to a first embodiment where a narrowing layer is a sealing layer. In FIG. 1a, a substrate 1 is provided, which may be a semiconductor substrate with a MEMS or NEMS device on the surface. A sacrificial layer 2 is deposited on the surface of the substrate 1 and a membrane layer 3 is deposited on top of the sacrificial layer 2. For example, the substrate 1 may be a silicon wafer; the sacrificial layer 2 may be a silicon oxide layer; and the membrane layer 3 may be Si or SiGe, preferably in a polycrystalline structure (e.g., a polysilicon layer or a polysilicon-germanium layer).

In FIG. 1b, release holes 4 are etched (e.g., by a dry etch process in combination with a known lithography step) in the membrane layer 3, stopping on the sacrificial layer 2. In FIG. 1c, a narrowing layer 5 is deposited conformally. This means that the narrowing layer 5 is deposited with substantially the same thickness on the entire exposed surface, including the side walls and bottom of the release holes 4.

The narrowing layer 5 is a sealing layer. The sealing layer material has a lower melting point than the membrane material. Preferably, the sealing layer is a metal or metal alloy layer. For example, the sealing layer comprises or consists of aluminium, germanium, gold, or indium. The sealing layer may also be a silicon oxide layer or a silicon nitride layer. The material of the sealing layer can be chosen in such a way that reflow can be performed at different temperatures in the range of 100° C.-1100° C. depending on the application.

The sealing layer may be a single layer or it may include a stack of layers in order to form an alloy during reflow. In this way, by choosing the layers of which the stack is composed, the reflow temperature may be controlled within a given range. The reflow material may be chosen in such a way as to be able to perform an outgassing before reflow at a temperature lower than the reflow temperature. An outgassing step is a known process step whereby residual vapor and gas is removed after a release step as described with respect to FIG. 1e.

In FIG. 1d, the sealing layer 5 is etched anisotropically, preferably by a dry etch process, stopping on the membrane layer 3 and on the sacrificial layer 2. This means that the sealing layer remains only on the side walls of the release holes 4.

In FIG. 1e, a portion of the sacrificial layer 2 is removed via the release holes 4 forming a cavity 6. This process is referred to as the “release step.” The removal of a portion of the sacrificial layer 2 may be performed using a wet or dry etch of the sacrificial layer 2. For example, an HF-based etch (e.g., Vapor HF (vHF)) may be used in the case of oxide used as the sacrificial layer 2. The substrate 1 may include a MEMS or NEMS device and the cavity 6 is formed so as to contain one or more of such devices.

In the embodiment depicted in FIG. 1e, the release step removes a portion of the sacrificial layer 2 and the side walls of the cavity 6 are formed by the remaining portion 8 of the sacrificial layer 2. Thus, the etch step is stopped at an appropriate time so as to obtain the cavity 6.

According to another embodiment, the sacrificial layer 2 may be surrounded by a structure, such as a support frame for the membrane. In this case, the entire sacrificial layer 2 is removed in the release step. Preferably, the material of the surrounding structure is such that a selective etch can be performed that automatically stops when all of the sacrificial layer material has been removed.

An outgassing step may be performed after the release step. Then a reflow of the sealing layer 5 is performed under controlled atmosphere and pressure. The reflow step may be performed in a reflow oven.

In FIG. 1f, droplets 7 of sealing layer material are formed at the lower end of the release holes 4. The droplets 7 may also be formed at the upper end or in between the ends of the release holes 4. Where the droplets 7 are located may depend on the geometry of the release holes 4 (e.g., slightly more narrow at one end compared to the other end). Deposition of the reflow material inside the cavity 6 is not possible because the gravitational force is negligible compared to the capillary force at the microscale. For example, in order to ensure that the capillary forces are sufficient to obtain this effect, the diameter of the release holes 4 may be about 1 micron, and the thickness of the sealing layer 5 may be a few hundreds of nanometres.

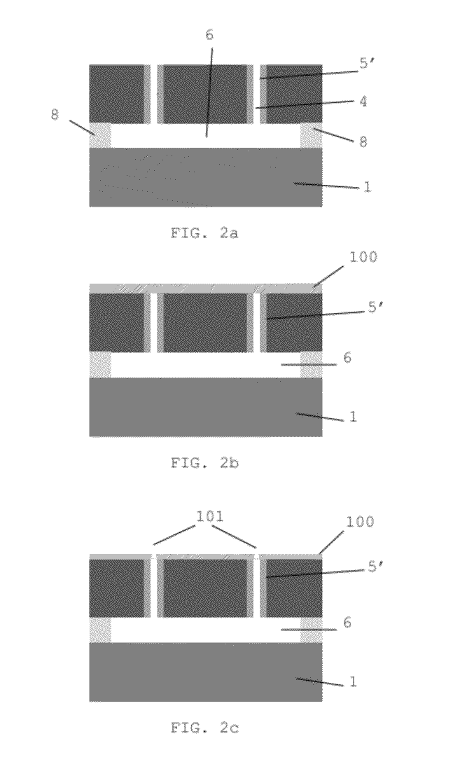

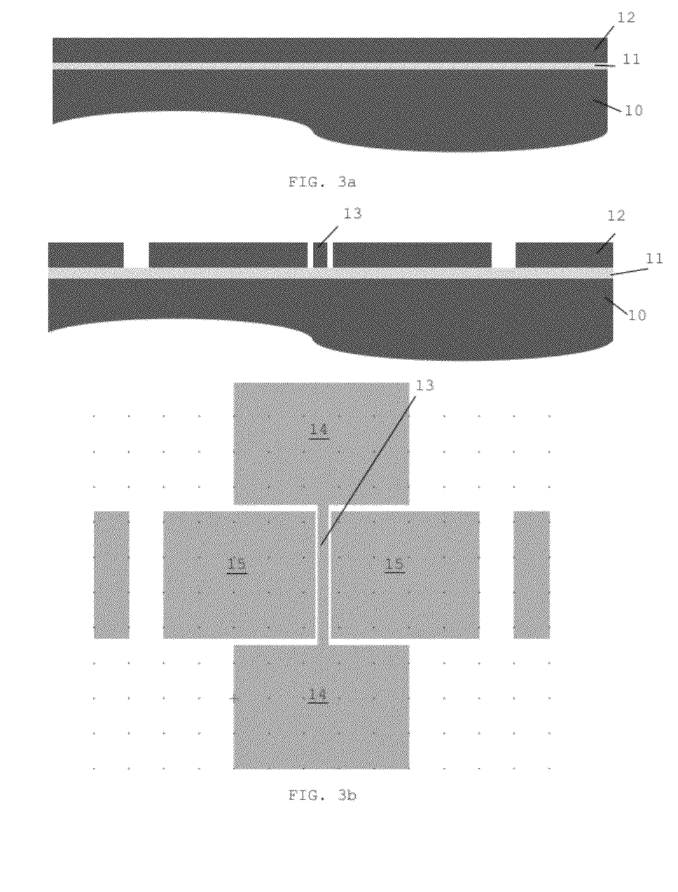

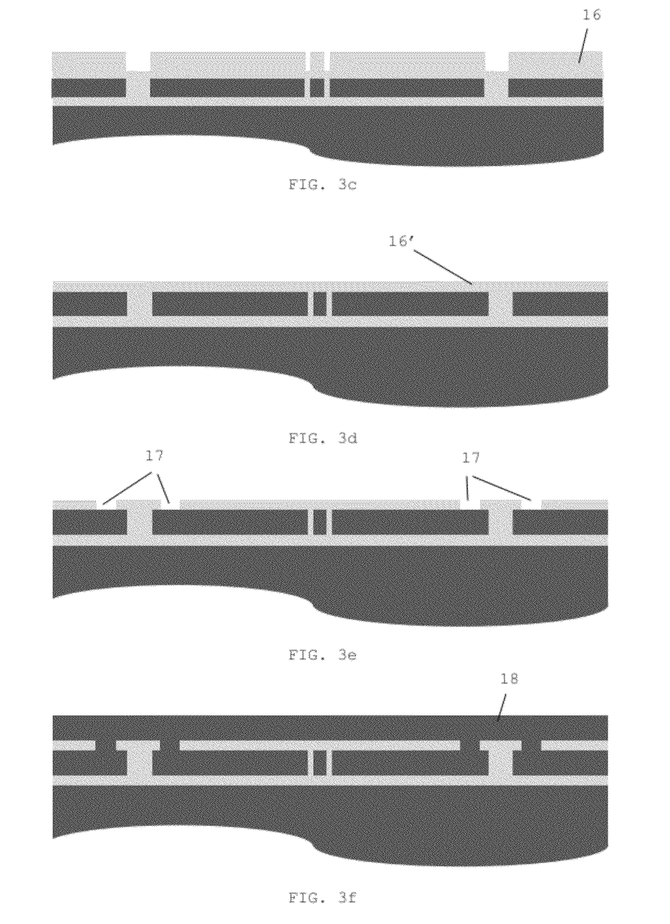

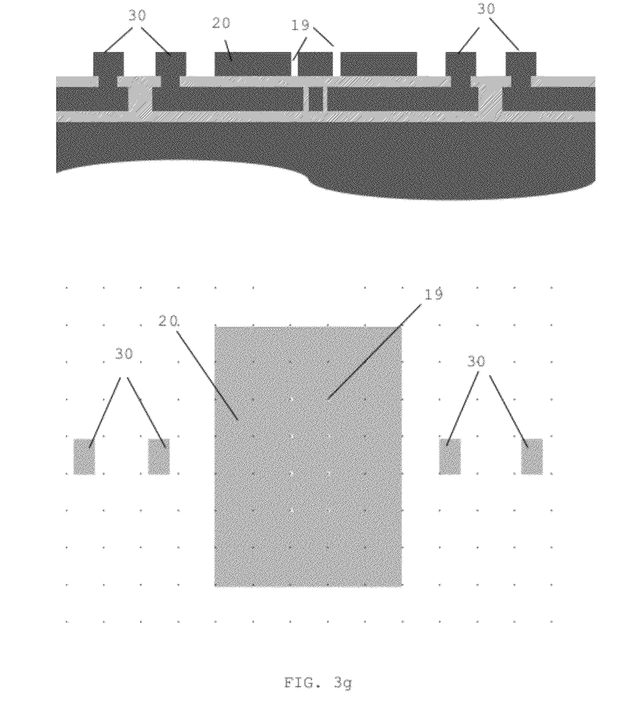

FIG. 2 illustrates a method for sealing a cavity, according to a second embodiment where the narrowing layer is not a sealing layer. In this embodiment, the narrowing layer is preferably a layer 5′ of the same material as the membrane layer, e.g., a polySiGe layer (although other suitable materials are possible). The steps depicted in FIGS. 1a to 1d are applicable to the second embodiment, where the sealing narrowing layer 5 is replaced by a non-sealing narrowing layer 5′.

FIG. 2a shows the non-sealing narrowing layer 5′ after the anistropic etch depicted in FIG. 1d. In FIG. 2b, a sealing layer 100 is deposited on top of the membrane layer 3 to directly close off the release holes 4 without a reflow step. Alternatively, the sealing layer 100 may be deposited in a thickness suitable for forming a collar 101 around the edge of the release holes 4 as depicted in FIG. 2c. A reflow step is then performed in order to close the collar 101.

The material of the sealing layer 100 may be any material known in the art to be suitable for this purpose, such as a metal (e.g., aluminium or gold), silicon oxide, and so on. The second embodiment with the non-sealing narrowing layer allows narrowing the release holes 4 in a SiGe membrane layer 3 of about 1 micron in diameter to about 100 nm or less, by depositing a SiGe narrowing layer 5′. This ensures that no sealing material drops into the cavity 6 during reflow of the sealing layer 100 (in the case of FIG. 2c). Also, the second embodiment allows application of a thin sealing layer 100, which may prevent problems related to thicker sealing layers (e.g., stress related delamination or leak path formation towards the cavity).

According to the first and second embodiments, instead of depositing a conformal layer followed by anisotropic etching, the narrowing layer 5, 5′ may be deposited directly on the side walls of the release holes 4 and only on the side walls, by a selective deposition technique (e.g., Atomic Layer Deposition (ALD)).

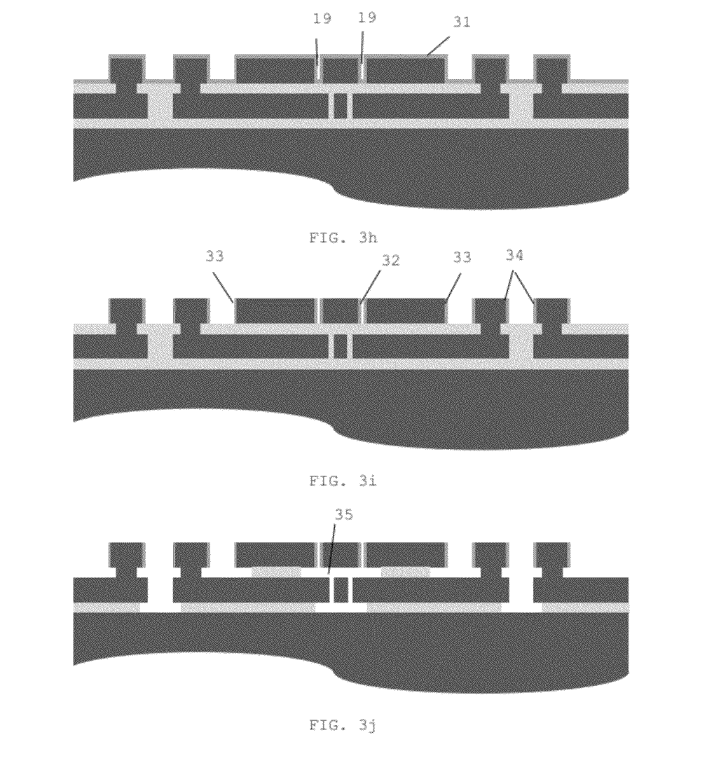

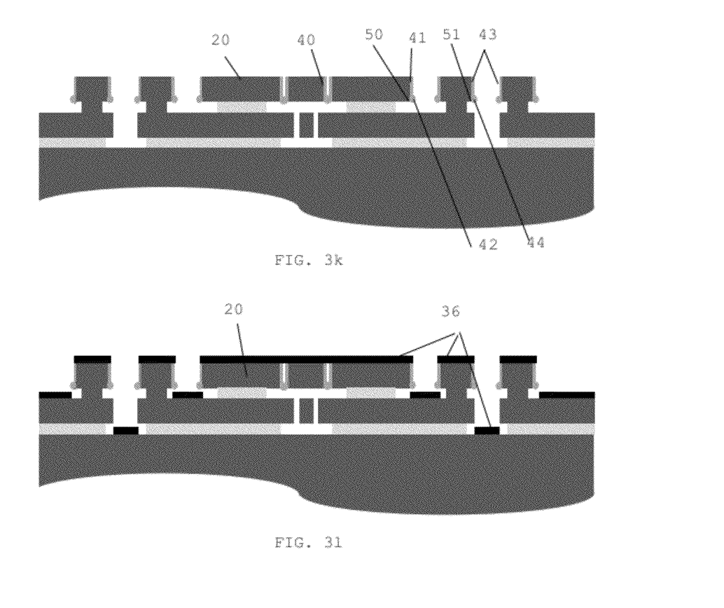

Advantageously, the method allows for etching away portions of the membrane layer 3 along with etching the release holes 4 to define a cap structure covering a MEMS device and/or to define bonding pads for contacting the MEMS device. A process flow for producing a capped MEMS device in this way is shown in FIGS. 3a to 31.

FIG. 3a shows a wafer consisting of a base substrate 10, an insulating layer 11, and a structural layer 12. The structural layer 12 is a semiconductor layer that includes one or more MEMS or NEMS devices. The wafer depicted in FIG. 3a may be produced from a semiconductor on insulator type wafer (SOI), i.e., silicon on insulator. The insulating layer 11 is of a material that can be etched during the release step. The structural layer 12 is produced in the semiconductor layer of the SOI.

In FIG. 3b, the structural layer 12 is etched to define a MEMS device 13. The etching step stops on the insulating layer 11. FIG. 3b also shows a top view of the MEMS device 13 illustrating the result of the etching step. Of course, the shape of a MEMS device varies for different device designs. The MEMS device in this example is a resonator, which is a beam 13 arranged between mechanical anchor regions 14. Parts 15 are RF ports (I/O).

In FIG. 3c, a sacrificial layer 16 is deposited on top of the patterned structural layer 12 filling the area surrounding the MEMS device 13. The sacrificial layer 16 may be of the same material as the insulating layer 11, e.g., silicon oxide.

In FIG. 3d, the sacrificial layer 16 is planarized using a known planarization technique, such as Chemical Mechanical Polishing (CMP), resulting in the planarized sacrificial layer 16′.

In FIG. 3e, openings 17 are etched in the planarized sacrificial layer 16′, stopping on the structural layer 12, in order to provide electrical feedthroughs.

In FIG. 3f, a membrane layer 18 is deposited, filling the openings 17 and forming a continuous layer on top of the structural layer 12 and the sacrificial layer 16′.

In FIG. 3g, the membrane layer 18 is etched to form release holes 19 and to define a portion 20 of the membrane layer 18 that will form the cap covering the MEMS device. Areas 30 of the membrane layer 18 remain on top of the openings 17 in the sacrificial layer 16′. The areas 30 will form contact pads for contacting the MEMS device 13. FIG. 3g also shows a top view of the result of the step of etching the membrane layer 18.

In FIG. 3h, a sealing layer 31 is deposited conformally on the membrane layer 18 and on the sacrificial layer 16′ so that the sealing layer 31 is present on the walls and bottom of the release holes 19, i.e., according to the first embodiment as described with respect to FIG. 1.

In FIG. 3i, the sealing layer 31 is etched back, stopping on the sacrificial layer 16′ and leaving a layer 32 of sealing material on the side walls of the release holes 19, a layer 33 of sealing material on the side walls of the cap 20, and a layer 34 of sealing material on the side walls of the bond pads 30.

In FIG. 3j, a release step is performed such that the sacrificial layer 16′ and the insulating layer 11 are partially removed, forming a cavity 35 with the MEMS device 13 inside the cavity. In this example, the insulating layer 11 forms an additional sacrificial layer already present on the substrate when the step of depositing a sacrificial layer 16 according to the method is applied. The release step can be done by a wet or dry etch of the sacrificial layer, preferably an HF-based etch (preferably vapor HF) in the case of oxide used as the sacrificial layer.

In FIG. 3k, a reflow step is performed: the substrate is heated up to a temperature above the melting point of the sealing layer 31, which is lower than the melting point of the membrane layer 18. The reflow of the sealing layer inside the release holes 19 seals off these holes.

In FIG. 31, a metal layer 36 is deposited to form the metallization for the bond pads 30. The metal layer 36 provides an additional sealing for the cavity 35.

The MEMS device 13 is encapsulated in the cavity 35 closed off by a membrane cap 20, having release holes 19 that are sealed by a portion of reflowed sealing material, wherein a layer 40 of the sealing material is present on the side walls of the release holes. When the release holes have been etched simultaneously with the etching of the membrane layer to define the cap 20 and the bonding pads 30, the side walls of the cap 20 are covered by a layer 41 of sealing material with a thicker portion 42 at the bottom, obtained by the reflow of the sealing material present on the side walls. The fact that the simultaneous etching has taken place is detectable by the fact that the thicker portion 42 extends downward with respect to the lower rim 50 of the cap's side wall. Likewise, on the side walls of the bond pads 30, a layer 43 of sealing material is present with a thickened portion 44 at the lower end, extending downward with respect to the lower rim 51 of the bond pads.

While FIG. 3 was described with respect to a MEMS device, the described process flow also applies to a NEMS device.

It is intended that the foregoing detailed description be regarded as illustrative rather than limiting and that it is understood that the following claims including all equivalents are intended to define the scope of the invention. The claims should not be read as limited to the described order or elements unless stated to that effect. Therefore, all embodiments that come within the scope and spirit of the following claims and equivalents thereto are claimed as the invention.

I claim:

1. A method for sealing a cavity, comprising:
providing a substrate;
depositing a sacrificial layer on the substrate;
depositing a membrane layer on the sacrificial layer;
etching at least one release hole in the membrane layer exposing the sacrificial layer;
forming a narrowing layer on the side walls of the at least one release hole;
removing at least a portion of the sacrificial layer via the release hole to form a cavity; and
closing the at least one release hole.

2. The method of claim 1, wherein closing the at least one release hole includes performing a reflow of the narrowing layer.

3. The method of claim 1, wherein closing the at least one release hole includes depositing a sealing layer on top of the membrane layer to close the at least one release hole directly.

4. The method of claim 1, wherein closing the at least one release hole includes depositing a sealing layer on top of the membrane layer and performing a reflow of the sealing layer.

5. The method of claim 1, wherein forming a narrowing layer includes:
depositing a conformal layer on the membrane layer and on side walls and bottom of the at least one release hole; and
anisotropically etching the conformal layer to leave the conformal layer only on the side walls of the at least one release hole.

6. The method of claim 1, wherein forming a narrowing layer includes depositing selectively the narrowing layer on the side walls of the at least one release hole.

7. The method of claim 1, wherein the narrowing layer is formed of a material same as the membrane layer.

8. The method of claim 1, wherein the narrowing layer is a metal or metal alloy layer.

9. The method of claim 8, wherein the narrowing layer includes at least one of aluminium, germanium, gold, and indium.

10. The method of claim 1, wherein the narrowing layer is a stack of layers.

11. The method of claim 1, wherein while etching the at least one release hole, further comprising etching the membrane layer to form a cap structure above the cavity.

12. The method of claim 1, wherein while etching the at least one release hole, further comprising etching the membrane layer to form contact pads.

13. The method of claim 1, further comprising depositing a metal layer on the membrane layer.

14. The method of claim 1, wherein the substrate comprises one or more Micro or Nano Electromechanical System devices, and wherein removing at least a portion of the sacrificial layer forms the cavity comprising the one or more Micro or Nano Electromechanical System devices.

15. The method of claim 1, wherein the substrate is formed of a base substrate, an insulator layer on the base substrate, and a structural semiconductor layer comprising one or more Micro or Nano Electromechanical System devices on the insulating layer, and wherein the at least a portion of the insulating layer is removed with the sacrificial layer, through the at least one release hole, so as to form the cavity comprising the one or more Micro or Nano Electromechanical System devices.

16. A system, comprising:
a Micro or Nano Electromechanical System device encapsulated in a cavity;
a cap covering the cavity;
at least one release hole in the cap; and
a sealing material that seals the at least one release hole and is located on side walls of the at least one release hole.

17. The system of claim 16, wherein a layer of the sealing material is present on side walls of the cap, the layer having a portion on a lower rim of the side walls of the cap, the portion being thicker than the rest of the layer, the portion extending downward with respect to the rim.

18. The system of claim 16, further comprising a metal layer on a top surface of the cap.
